(19) United States
(12) Patent Application Publication
(10) Pub. No.: US 2013/0071220 A1
(43) Pub. Date: Mar. 21, 2013

(54) SEMICONDUCTOR CHIP PICK-UP METHOD AND SEMICONDUCTOR CHIP PICK-UP APPARATUS

(71) Applicant: Nao KURODA, Himeji-shi (JP)

(72) Inventor: Nao KURODA, Himeji-shi (JP)

(73) Assignee: Kabushiki Kaisha Toshiba, Tokyo (JP)

(21) Appl. No.: 13/424,322

(22) Filed: Mar. 19, 2012

(30) Foreign Application Priority Data
Sep. 20, 2011 (JP) 2011-204364

(51) Int. Cl. H01L 21/67

(52) U.S. Cl. 414/785; 414/800

(57) ABSTRACT

A semiconductor chip pick-up method includes: pushing up each of semiconductor chips divided through dicing using a plurality of push-up pins; lowering some of the plurality of push-up pins; and picking up the semiconductor chip after being pushed up using a collet.

### CROSS-REFERENCE TO RELATED APPLICATION

This application is based upon and claims the benefit of priority from the prior Japanese Patent Application No. 2011-204364, filed on Sep. 20, 2011; the entire contents of which are incorporated herein by reference.

### FIELD

Embodiments described herein relate generally to a semiconductor chip pick-up method and a semiconductor chip pick-up apparatus.

### BACKGROUND

On a semiconductor substrate (referred to as a wafer, hereinafter), a large number of semiconductor elements are collectively formed. The back side (rear surface) of the wafer on which the large number of semiconductor elements are formed is grinded by a grinding apparatus to reduce a thickness of the wafer to a predetermined thickness, an adhesive sheet (dicing tape) formed of a synthetic resin or the like is then attached to the back side of the wafer, and individual semiconductor elements are divided by a dicing apparatus to form semiconductor chips. The semiconductor chips divided by the dicing apparatus are subjected to predetermined inspection, and then good chips which passed the inspection are picked up to be put on the market. When picking up the good semiconductor chips, a semiconductor chip pick-up apparatus has been used.

### BRIEF DESCRIPTION OF THE DRAWINGS

FIG. 1A to FIG. 1C are explanatory diagrams of a dicing process of a wafer.

FIG. 2 is a structural diagram of a pick-up apparatus according to an embodiment.

FIG. 3A and FIG. 3B are structural diagrams of a push-up mechanism.

FIG. 4A to FIG. 6B are explanatory diagrams of a semiconductor chip pick-up method.

### DETAILED DESCRIPTION

In a semiconductor chip pick-up method according to respective embodiments, each of semiconductor chips divided through dicing is pushed up by a plurality of push-up pins, some of the plurality of push-up pins are lowered, and then the pushed-up semiconductor chip is picked up by a collet.

Hereinafter, an embodiment will be described with reference to the drawings.

### Embodiment

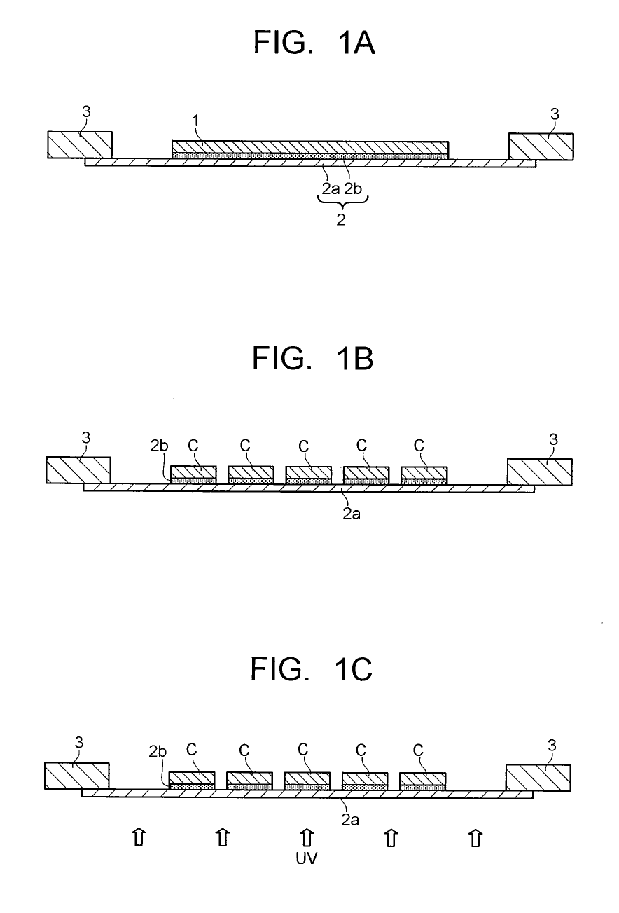

FIG. 1A to FIG. 1C are explanatory diagrams of a dicing process of a semiconductor substrate 1 (referred to as a wafer 1, hereinafter). First, explanation will be made on the dicing process of the wafer 1 on which a large number of semiconductor elements are formed, with reference to FIG. 1A to FIG. 1C.

On a front side (front surface) of the wafer 1, the large number of semiconductor elements are formed. A thickness of the wafer 1 is reduced by grinding a back side (rear surface) of the wafer 1 to a predetermined thickness (30 to 80 μm, for instance). The thickness-reduced wafer 1 is attached to an adhesive sheet 2 for dicing. The adhesive sheet 2 to which the thickness-reduced wafer 1 is attached is stretched so that its outer peripheral portion is not loosened, and is attached to a metal frame 3 (refer to FIG. 1A).

The adhesive sheet 2 includes a sheet base material 2a and an adhesive layer 2b provided on one side (wafer 1 side) of the sheet base material 2a. The sheet base material 2a is a resin sheet having an expansion/contraction property such as PVC (polyvinyl chloride) and PET (polyethylene terephthalate), for example. As the adhesive layer 2b, one having a property that an adhesion is lowered due to curing caused by irradiation of ultraviolet ray (UV), is preferably used.

The wafer 1 attached onto the adhesive sheet 2 is divided into semiconductor chips C by dicing (refer to FIG. 1B).

After the wafer is divided, ultraviolet ray UV is irradiated to the adhesive sheet 2, which causes curing of the adhesive layer 2b of the adhesive sheet 2 to lower the adhesion of the adhesive layer (refer to FIG. 1C).

The divided semiconductor chips C are subjected to predetermined inspection, and then good chips which passed the inspection are picked up by a pick-up apparatus of the semiconductor chip C according to the embodiment to be described next.

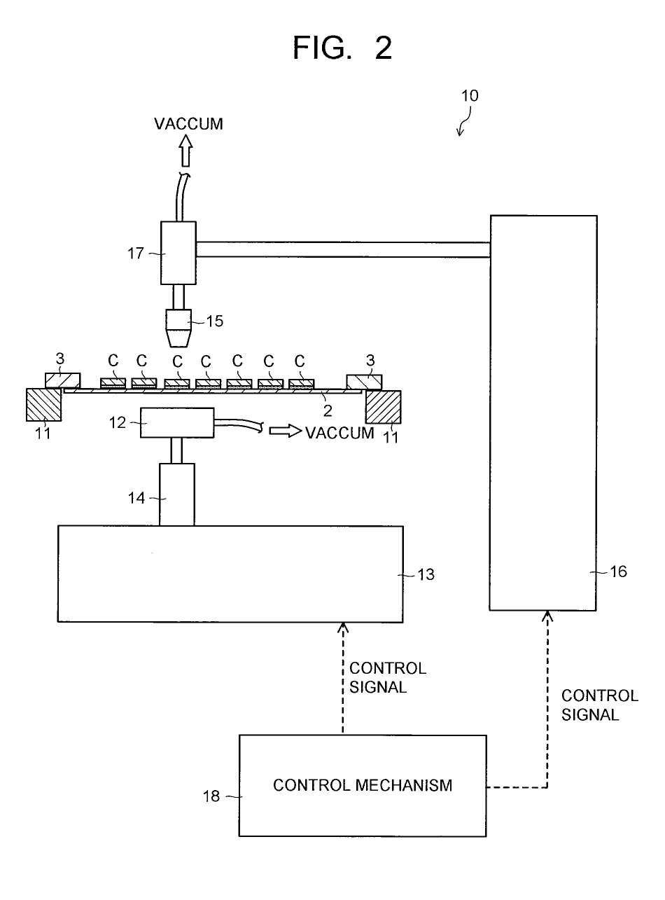

FIG. 2 is a structural diagram of a pick-up apparatus 10 of the semiconductor chip C according to the embodiment. Hereinafter, the structure of the pick-up apparatus 10 according to the embodiment will be described with reference to FIG. 2.

The pick-up apparatus 10 includes a fixing jig 11, a push-up mechanism 12, an X-Y stage 13, a cylinder 14, a collet 15, a drive mechanism 16, a cylinder 17 and a control mechanism 18. Note that the push-up mechanism 12 and the collet 15 are connected to not-shown vacuum pumps.

The fixing jig 11 holds the metal frame 3 that grips the outer peripheral portion of the adhesive sheet 2 to which the large number of semiconductor chips C divided in the dicing process are adhered. The push-up mechanism 12 pushes up the individual semiconductor chips C from the back side (lower side). The X-Y stage 13 drives the push-up mechanism 12 in a horizontal direction with respect to the semiconductor chips C on the adhesive sheet 2, thereby performing positioning in the horizontal direction. The cylinder 14 drives the push-up mechanism 12 in a vertical direction with respect to the semiconductor chips C on the adhesive sheet 2.

The collet 15 sucks the semiconductor chip C pushed up by the push-up mechanism 12 to pick up the chip. The drive mechanism 16 drives the collet 15 in the horizontal direction with respect to the semiconductor chips C on the adhesive sheet 2, thereby performing positioning in the horizontal direction. The cylinder 17 drives the collet 15 in the vertical direction with respect to the semiconductor chips C on the adhesive sheet 2. The control mechanism 18 controls the pick-up apparatus 10.

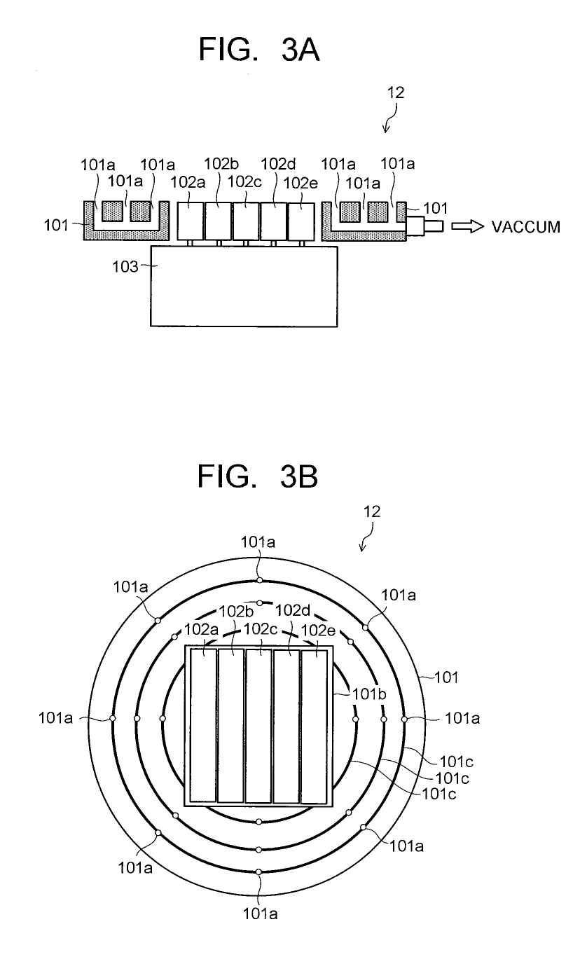

FIG. 3A is a sectional view of the push-up mechanism 12. FIG. 3B is a plan view of the push-up mechanism 12. Hereinafter, explanation will be made on a structure of the push-up mechanism 12 with reference to FIG. 3A and FIG. 3B. The push-up mechanism 12 includes a suction stage 101, a plurality of push-up pins 102a to 102e and a raising/lowering mechanism 103 (pin holder). On a surface of the suction stage 101, a plurality of suction holes 101a for sucking the rear surface of the adhesive sheet 2 are provided inside grooves 101c. On a center portion of the surface of the suction stage 101, an opening 101b is provided.

A shape of each of the push-up pins 102a to 102e is a rectangular parallelepiped shape. These push-up pins 102a to 102e are provided, in parallel, inside the opening 101b provided on the center portion of the surface of the suction stage 101. A surface of each of the push-up pins 102a to 102e (push-up surface) has a shape of rectangle (oblong), and is flat (flat surface), different from a conventional push-up pin.

In this embodiment, by setting the surface of each of the push-up pins 102a to 102e to the flat surface, a contact area at the time of pushing up the semiconductor chip C is enlarged. For this reason, it is possible to reduce a stress generated when pushing up the semiconductor chip C. In addition to that, since the contact area is large, a positional displacement in which a position and an angle of the semiconductor chip C are displaced when pushing up the semiconductor chip C, is difficult to occur. In FIG. 3A and FIG. 3B, the number of push-up pins is five, but is not limited to the number, and it is only required to provide a plurality of numbers of pins.

The raising/lowering mechanism 103 includes small-sized air cylinders (not shown) for raising/lowering the push-up pins 102a to 102e disposed, in parallel, inside the opening 101b. The air cylinders are driven by air supplied from the outside. The raising/lowering mechanism 103 includes the air cylinders for respective push-up pins 102a to 102e, for raising/lowering each of the push-up pins 102a to 102e independently. As a mechanism for raising/lowering the push-up pins 102a to 102e, various types of mechanisms can be applied. For instance, it is also possible to design such that the push-up pins 102a to 102e are raised/lowered by using electromagnetic cylinders, small-sized motors or the like.

The raising/lowering mechanism 103 can raise/lower each of the push-up pins 102a to 102e independently. Therefore, it is possible to change the number of push-up pins to be raised/lowered, depending on a size of the semiconductor chip C. As a result of this, it is possible to change the number of push-up pins in accordance with a type (model) of the semiconductor chip.

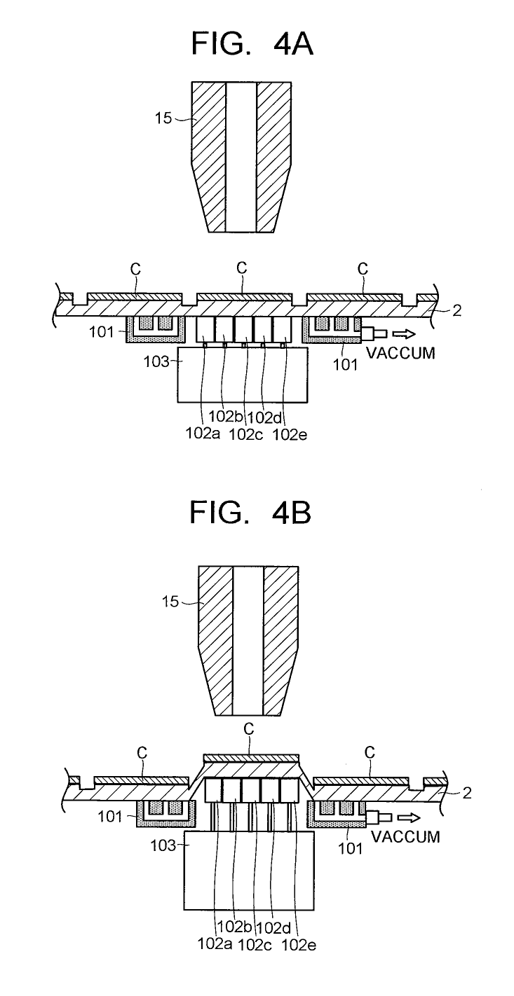

FIG. 4A to FIG. 6B are explanatory diagrams of a pick-up method of the semiconductor chip C using the pick-up apparatus 10 according to this embodiment. Hereinafter, explanation will be made on a pick-up of the semiconductor chip C using the pick-up apparatus 10, with reference to FIG. 2 to FIG. 6B. Note that the X-Y stage 13, the cylinder 14, the drive mechanism 16, the cylinder 17, the raising/lowering mechanism 103 and the like are controlled by the control mechanism 18.

### (First Process: Refer to FIG. 4A)

The drive mechanism 16 is controlled, thereby performing positioning so that the collet 15 is positioned right above the semiconductor chip C being a pick-up target. Further, the X-Y stage 13 is controlled, thereby performing positioning so that the push-up pins 102a to 102e provided inside the opening 101b of the suction stage 101 of the push-up mechanism 12 are positioned right below the semiconductor chip C being the pick-up target. Thereafter, the push-up mechanism 12 is raised by the cylinder 14, thereby making the suction stage 101 abut on the rear surface of the adhesive sheet 2. Next, by performing evacuation through the suction holes 101a, the rear surface of the adhesive sheet 2 is vacuum-sucked.

### (Second Process: Refer to FIG. 4B)

The raising/lowering mechanism 103 is controlled, thereby making the push-up pins 102a to 102e disposed, in parallel, inside the opening 101b of the suction stage 101 to be raised to a predetermined height at the same time and at the same speed. When the push-up pins 102a to 102e are raised, the semiconductor chip C being the pick-up target is pushed up by a predetermined amount via the adhesive sheet 2. Note that the same time and the same speed mentioned here do not mean exactly the same time and the same speed, and they may not be exactly the same time and the same speed as long as they fall within a range in which troubles such as a crack and a chip of the semiconductor chip C due to the stress do not occur.

As described above, in this embodiment, the surface of each of the push-up pins 102a to 102e is flat (flat surface), and the push-up pins 102a to 102e perform the push-up operation at the same time. For this reason, it is possible to enlarge the contact area at the time of pushing up the semiconductor chip C. As a result of this, it is possible to reduce the stress with respect to the semiconductor chip C generated when the semiconductor chip C is pushed up. Further, the positional displacement in which the position and the angle of the semiconductor chip C are displaced when pushing up the semiconductor chip, is difficult to occur.

An amount of push-up (height) of the push-up pins 102a to 102e is set to an amount (height) at which the adhesive sheet 2 is not broken. Since an amount of stretch of the sheet is different depending on the adhesive sheet 2 to be used, it is preferable that the amount of push-up (height) of the push-up pins 102a to 102e is appropriately adjusted in accordance with the amount of stretch of the adhesive sheet 2.

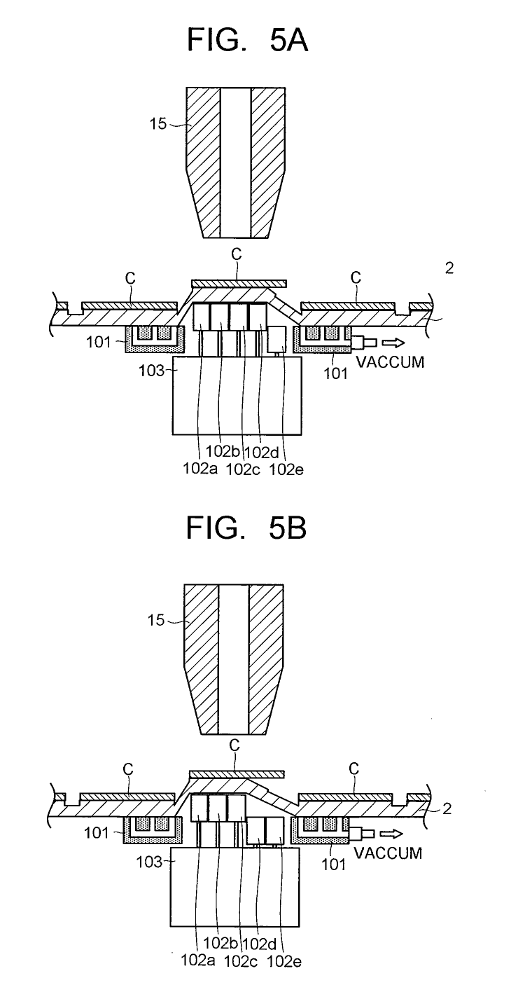

### (Third Process: Refer to FIG. 5A)

After the push-up pins 102a to 102e are raised by the predetermined amount, the raising/lowering mechanism 103 is controlled to lower the push-up pin 102e at the right end. Here, the adhesive sheet 2 in the periphery of the semiconductor chip C being the pick-up target is sucked to the suction stage 101, and has the expansion/contraction property. For this reason, the adhesive sheet 2 at an end portion of the semiconductor chip C is in a state of being pulled toward the suction stage 101 side. As a result of this, when the push-up pin 102e is lowered, the adhesive sheet 2 between the back side (rear surface) of the semiconductor chip C and the push-up pin 102e is peeled off from the back side of the semiconductor chip C.

### (Fourth Process: Refer to FIG. 5B)

After the push-up pin 102e is lowered, the raising/lowering mechanism 103 is controlled to lower the push-up pin 102d. When the push-up pin 102d is lowered, the adhesive sheet 2 between the back side of the semiconductor chip C and the push-up pin 102d is peeled off from the back side of the semiconductor chip C.

The push-up pins 102d, 102e are lowered in FIG. 5A and FIG. 5B, but, in addition to that, the push-up pin 102c may also be lowered as well. Further, in FIG. 5A and FIG. 5B, the push-up pins 102e and 102d from the right end when facing the drawings are lowered, but, it is also possible to lower the push-up pins 102a and 102b from the left end when facing the drawings.

By lowering the push-up pins from the right end or left end, it is possible to reduce an area of the back side of the semiconductor chip C adhered to the adhesive sheet 2. For this reason, when picking up the semiconductor chip C using the collet 15 in a later-described process, it is possible to reduce a stress applied to the semiconductor chip.

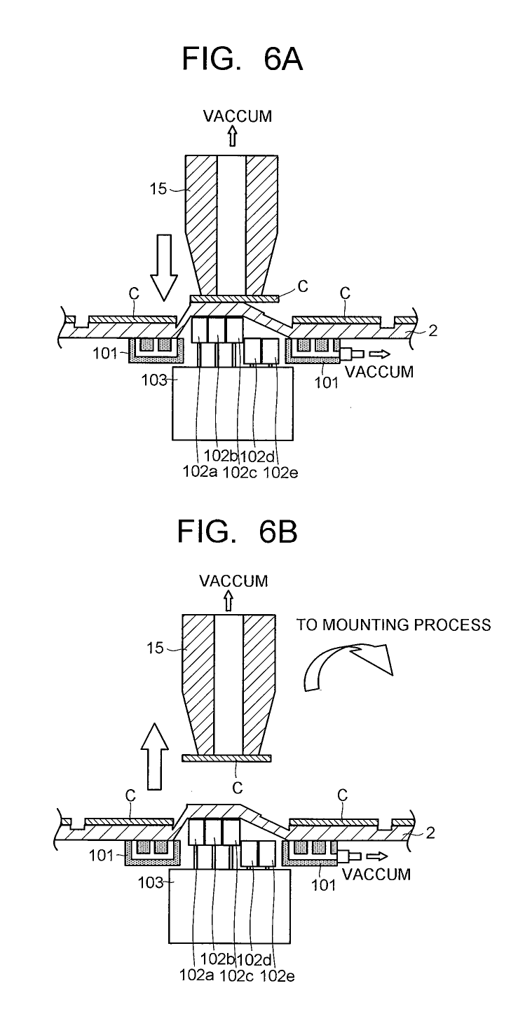

### (Fifth Process: Refer to FIG. 6A)

The cylinder 17 is controlled to lower the collet 15 so that a tip portion of the collet 15 abuts on the front surface of the semiconductor chip C being the pick-up target. Next, the semiconductor chip C being the pick-up target is sucked.

### (Sixth Process: Refer to FIG. 6B)

The cylinder 17 is controlled to raise the collet 15 in a state where the semiconductor chip C is being sucked. Next, with the use of the drive mechanism 16, the picked-up semiconductor chip C is mounted on a predetermined position on a lead frame. Each of the other semiconductor chips C is also picked up in a similar manner to be mounted on a predetermined position on a lead frame.

As described above, in the pick-up apparatus 10 according to this embodiment, the surface of each of the push-up pins 102a to 102e is the flat surface, and the push-up pins 102a to 102e perform the push-up operation at the same time. For this reason, it is possible to enlarge the contact area at the time of pushing up the semiconductor chip C. As a result of this, it is possible to reduce the stress with respect to the semiconductor chip C generated when pushing up the semiconductor chip C. Further, since the contact area when pushing up the semiconductor chip C is large, the positional displacement in which the position and the angle of the semiconductor chip C are displaced when pushing up the semiconductor chip, is difficult to occur.

Further, since the semiconductor chip C is picked up after lowering some of the push-up pins 102a to 102e from the end, it is possible to reduce the area of the back side of the semiconductor chip C adhered to the adhesive sheet 2. For this reason, when picking up the semiconductor chip C in the following process, it is possible to reduce the stress applied to the semiconductor chip.

### (Modified Example of the Embodiment)

In the embodiment, after the push-up pins 102a to 102e are raised by the predetermined amount at the same time (refer to FIG. 4B), some of the push-up pins 102a to 102e are lowered one by one from the end while keeping a certain amount of push-up of the push-up pins, namely, while keeping a certain amount of push-up of the semiconductor chip C (refer to FIG. 5A to FIG. 6A).

However, it is also possible to design such that, after the push-up pins 102a to 102e are raised by the predetermined amount at the same time, the amount of push-up of the push-up pins, namely, the amount of push-up of the semiconductor chip C is increased by a predetermined amount every time the push-up pin is lowered when some of the push-up pins 102a to 102e are lowered one by one from the end. In this case, every time the amount of push-up of the push-up pins is increased, the force to pull the adhesive sheet 2 at the end portion of the semiconductor chip C toward the suction stage 101 side is increased. Accordingly, there is provided an effect that the adhesive sheet 2 becomes easily peeled off from the back side of the semiconductor chip C.

Note that as the mechanism for raising/lowering the push-up pins 102a to 102e, various types of mechanisms can be applied, similar to the embodiment, but, it is preferable to use one capable of controlling the amount of push-up in a plurality of stages, such as an electromagnetic cylinder and a small-sized motor, for example, on the ground that the amount of push-up of the semiconductor chip C is increased by the predetermined amount every time the push-up pin is lowered.

### Other Embodiments

While certain embodiments have been described, these embodiments have been presented by way of example only, and are not intended to limit the scope of the inventions. Indeed, the novel embodiments described herein may be embodied in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor chip pick-up method, comprising:
pushing up each of semiconductor chips divided through dicing using a plurality of push-up pins;
lowering some of the plurality of push-up pins; and
picking up the semiconductor chip after being pushed up using a collet.

2. The method according to claim 1,
wherein the plurality of push-up pins are disposed in parallel; and
wherein, in the lowering of the push-up pins, some of the plurality of push-up pins disposed in parallel are lowered one by one from an end.

3. The method according to claim 2,
wherein when some of the plurality of push-up pins disposed in parallel are lowered one by one from the end, an amount of push-up of the semiconductor chip is increased by a predetermined amount every time the push-up pin is lowered.

4. The method according to claim 1,
wherein when pushing up the semiconductor chips, the push-up pins are raised at the same time and at the same speed.

5. A semiconductor chip pick-up apparatus, comprising:
a plurality of push-up pins pushing up each of semiconductor chips divided through dicing;
a raising/lowering mechanism raising/lowering each of the plurality of push-up pins independently; and
a collet picking up the semiconductor chip after being pushed up,
wherein the raising/lowering mechanism pushes up the semiconductor chip using the plurality of push-up pins and then lowers some of the push-up pins; and
wherein the collet picks up the semiconductor chip after some of the push-up pins are lowered.

6. The apparatus according to claim 5,
wherein the plurality of push-up pins are disposed in parallel; and
wherein the raising/lowering mechanism lowers some of the plurality of push-up pins disposed in parallel one by one from an end.

7. The apparatus according to claim 6,
wherein, when the raising/lowering mechanism lowers some of the plurality of push-up pins disposed in parallel one by one from the end, it increases an amount of push-up of the semiconductor chip by a predetermined amount every time the push-up pin is lowered.

8. The apparatus according to claim 5,
wherein a surface of each of the plurality of push-up pins for pushing up the semiconductor chip is flat.

9. The apparatus according to claim 5,
wherein the raising/lowering mechanism raises the plurality of push-up pins at the same time and at the same speed.

10. The apparatus according to claim 5,
wherein the raising/lowering mechanism comprises air cylinders or motors.

11. The apparatus according to claim 5,
wherein a surface of each of the plurality of push-up pins for pushing up the semiconductor chip has a shape of rectangle.
